(19) United States
(12) Patent Application Publication
(10) Pub. No.: US 2026/0317657 A1
(43) Pub. Date: Oct. 15, 2026

(54) H2O2 CLEANING COMPOSITION FOR POST-CMP CLEANING

(71) Applicant: ENTEGRIS, INC., Billerica, MA (US)

(72) Inventors: Atanu Das, Southbury, CT (US); Michael L. White, Ridgefield, CT (US); Daniela White, Ridgefield, CT (US); Sudeep Pallikkara Kuttiatoor, Naperville, IL (US)

(21) Appl. No.: 19/638,570

(22) Filed: Apr. 3, 2026

Related U.S. Application Data
(60) Provisional application No. 63/786,102, filed on Apr. 9, 2025.

(51) Int. Cl. C11D 3/39; C11D 3/04; C11D 3/36; C11D 3/37; H10P 70/00

(52) U.S. Cl. CPC C11D 3/3942; C11D 3/046; C11D 3/361; C11D 3/378; H10P 70/237

(57) ABSTRACT

The invention provides a composition comprising: (a) water, (b) hydrogen peroxide, (c) a complexant, (d) a fluoride salt, and (e) a sulfonated polymer. The invention also provides a method for removing residue from a surface of a microelectronic device substrate comprising contacting the surface of the microelectronic device substrate with the compositions described herein.

### BACKGROUND OF THE INVENTION

Microelectronic device wafers are used to form integrated circuits and include a substrate, such as silicon, on which regions are patterned for deposition of different materials having insulative, conductive or semi-conductive properties. To obtain the correct patterning, excess material used in forming the layers on the substrate must be removed. Further, to fabricate functional and reliable circuitry, it is important to prepare a flat or planar microelectronic wafer surface prior to subsequent processing. Thus, it is necessary to remove and/or polish certain surfaces of a microelectronic device wafer.

Chemical Mechanical Polishing or Planarization (“CMP”) is a process in which material is physically and chemically removed from a surface of a microelectronic device wafer. The surface is polished (more specifically, planarized) by coupling a physical process such as abrasion with a chemical process such as oxidation or chelation. In its most rudimentary form, CMP involves applying slurry, e.g., a dispersion of an abrasive (e.g., a ceria abrasive) and an active chemistry, to a polishing pad that buffs the surface of a microelectronic device wafer to achieve the removal, planarization, and polishing processes. It is not desirable for the removal or polishing process to be comprised of purely physical or purely chemical action, but rather it is the synergistic combination of both that achieves fast, uniform removal.

Following CMP processing, particles, residue, and other contaminants may be present on the surface of the microelectronic device. As a result, post-CMP removal compositions have been developed to remove the post-CMP residue (e.g., particles and contaminants), which may interfere with subsequent device processing steps. However, often these post-CMP removal compositions unintentionally at least partially remove other materials from the device surface that should remain.

For example, dielectric substrates polished with slurries comprising ceria abrasive particles often have nano-ceria abrasive particle residue present on the surface of the dielectric substrate, which can result in elevated surface defects. Without wishing to be bound by any particular theory, it is believed that the presence of nano-ceria abrasive particle residue can be attributed to robust interactions between the ceria abrasive particles and the dielectric surface via covalent, hydrogen-bonding, and Van der Waals forces.

Thus, there remains a need in the art for new, useful, and improved cleaning compositions, and specific ingredients are continually sought, especially for use with new microelectronic device structures such as those polished with a polishing slurry comprising a ceria abrasive. The invention provides such cleaning compositions and uses. These and other advantages of the invention, as well as additional inventive features, will be apparent from the description of the invention provided herein.

### BRIEF SUMMARY OF THE INVENTION

The invention provides a composition comprising (a) water, (b) hydrogen peroxide, (c) a complexant, (d) a fluoride salt, and (e) a sulfonated polymer.

The invention also provides a kit comprising (a) hydrogen peroxide, (b) a complexant, (c) a fluoride salt, and (d) a sulfonated polymer, as described herein.

The invention further provides a method for removing residue from a surface of a microelectronic device substrate, the method comprising (i) contacting the surface of the microelectronic device substrate with a composition comprising (a) water, (b) hydrogen peroxide, (c) a complexant, (d) a fluoride salt, and (e) a sulfonated polymer, and (ii) removing at least a portion of the residue from the surface of the microelectronic device substrate.

### DETAILED DESCRIPTION OF THE INVENTION

The invention provides a composition comprising (a) water, (b) hydrogen peroxide, (c) a complexant, (d) a fluoride salt, and (e) a sulfonated polymer.

The composition comprises water. The water can be any suitable water and can be, for example, deionized water (DIW) or distilled water. Water can be present in the composition from any source, such as by being contained in a component that is combined with other components to produce a composition in the form of a concentrate; as water combined in pure form to other components of a concentrate; or as water added to a concentrate, e.g., at a point of use, as dilution water for the purpose of diluting a concentrate to a desirable concentration for use.

The composition can comprise any suitable amount of water. For example, the amount of water can be a particular amount for preparing a concentrate, or a particular amount to provide a desirable concentration for use, which concentration for use is generally a higher amount relative to the amount of water in a concentrate. In some embodiments, the composition exists as a concentrate and comprises from about 5 wt. % to about 90 wt. % water, based on the total weight of the composition, for example, from about 10 wt. % to about 90 wt. %, from about 20 wt. % to about 90 wt. %, from about 30 wt. % to about 90 wt. %, from about 40 wt. % to about 90 wt. %, from about 50 wt. % to about 90 wt. %, from about 60 wt. % to about 90 wt. %, from about 70 wt. % to about 90 wt. %, from about 5 wt. % to about 80 wt. %, from about 10 wt. % to about 80 wt. %, from about 20 wt. % to about 80 wt. %, from about 30 wt. % to about 80 wt. %, from about 40 wt. % to about 80 wt. %, from about 50 wt. % to about 80 wt. %, from about 60 wt. % to about 80 wt. %, or from about 70 wt. % to about 80 wt. % water based on the total weight of the composition.

Upon dilution, the amount of water in the composition will be increased, such that, in embodiments, the diluted composition comprises from about 70 wt. % to about 99.99 wt. % water, based on the total weight of the composition, for example, from about 70 wt. % to about 99.9 wt. %, from about 70 wt. % to about 99.5 wt. %, from about 70 wt. % to about 99 wt. %, from about 70 wt. % to about 98 wt. %, from about 70 wt. % to about 95 wt. %, from about 80 wt. % to about 99.99 wt. %, from about 80 wt. % to about 99.9 wt. %, from about 80 wt. % to about 99.5 wt. %, from about 80 wt. % to about 99 wt. %, from about 80 wt. % to about 98 wt. %, from about 80 wt. % to about 95 wt. %, from about 90 wt. % to about 99.99 wt. %, from about 90 wt. % to about 99.9 wt. %, from about 90 wt. % to about 99.5 wt. %, from about 90 wt. % to about 99 wt. %, from about 90 wt. % to about 98 wt. %, from about 90 wt. % to about 95 wt. %, from about 95 wt. % to about 99.99 wt. %, from about 95 wt. % to about 99.9 wt. %, from about 95 wt. % to about 99.5 wt. %, from about 95 wt. % to about 99 wt. %, or from about 95 wt. % to about 98 wt. % water based on the total weight of the composition. In some embodiments, the diluted composition comprises from about 70 wt. % to about 99.9 wt. % water.

The composition comprises hydrogen peroxide. Without wishing to be bound by any particular theory, it is believed that the hydrogen peroxide (H₂O₂) can act as a reducing agent to eliminate metal residue (e.g., ceria abrasive residue) from the dielectric surface. For example, under low pH conditions, hydrogen peroxide (H₂O₂) efficiently transforms Ce(IV) to Ce(III), which, in the presence of a suitable complexant, forms a soluble Ce(III)-complex species. In other words, despite hydrogen peroxide (H₂O₂) being generally known as an oxidizing agent, hydrogen peroxide (H₂O₂) can act as a reducing agent to eliminate metal residue (e.g., ceria abrasive residue) from the dielectric surface.

The composition can comprise any suitable amount of hydrogen peroxide. The composition can comprise about 10 wt. % or less of hydrogen peroxide based on the total weight of the composition, for example, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, about 0.5 wt. % or less, about 0.4 wt. % or less, about 0.3 wt. % or less, about 0.2 wt. % or less, or about 0.1 wt. % or less of hydrogen peroxide based on the total weight of the composition. Alternatively, or in addition, the composition can comprise about 0.005 wt. % or more of hydrogen peroxide based on the total weight of the composition, for example, about 0.01 wt. % or more, 0.05 wt. % or more, about 0.1 wt. % or more, about 0.2 wt. % or more, about 0.3 wt. % or more, about 0.4 wt. % or more, or about 0.5 wt. % or more of hydrogen peroxide based on the total weight of the composition. Thus, the composition can comprise hydrogen peroxide in any amount bounded by any two of the aforementioned endpoints, as appropriate.

For example, in some embodiments, hydrogen peroxide can be present in the composition in an amount of about 0.005 wt. % to about 10 wt. % based on the total weight of the composition, e.g., about 0.005 wt. % to about 5 wt. %, about 0.005 wt. % to about 4 wt. %, about 0.005 wt. % to about 3 wt. %, about 0.005 wt. % to about 2 wt. %, about 0.005 wt. % to about 1 wt. %, about 0.005 wt. % to about 0.8 wt. %, about 0.005 wt. % to about 0.6 wt. %, about 0.005 wt. % to about 0.5 wt. %, about 0.005 wt. % to about 0.4 wt. %, about 0.005 wt. % to about 0.2 wt. %, about 0.005 wt. % to about 0.1 wt. %, 0.01 wt. % to about 5 wt. %, 0.01 wt. % to about 4 wt. %, 0.01 wt. % to about 3 wt. %, 0.01 wt. % to about 2 wt. %, about 0.01 wt. % to about 1 wt. %, about 0.01 wt. % to about 0.8 wt. %, about 0.01 wt. % to about 0.6 wt. %, about 0.01 wt. % to about 0.5 wt. %, about 0.01 wt. % to about 0.4 wt. %, about 0.01 wt. % to about 0.2 wt. %, about 0.01 wt. % to about 0.1 wt. %, 0.05 wt. % to about 5 wt. %, 0.05 wt. % to about 4 wt. %, 0.05 wt. % to about 3 wt. %, 0.05 wt. % to about 2 wt. %, about 0.05 wt. % to about 1 wt. %, about 0.05 wt. % to about 0.8 wt. %, about 0.05 wt. % to about 0.6 wt. %, about 0.05 wt. % to about 0.5 wt. %, about 0.05 wt. % to about 0.4 wt. %, about 0.05 wt. % to about 0.2 wt. %, about 0.05 wt. % to about 0.1 wt. %, about 0.1 wt. % to about 5 wt. %, about 0.1 wt. % to about 4 wt. %, about 0.1 wt. % to about 3 wt. %, about 0.1 wt. % to about 2 wt. %, about 0.1 wt. % to about 1 wt. %, about 0.1 wt. % to about 0.8 wt. %, about 0.1 wt. % to about 0.6 wt. %, or about 0.1 wt. % to about 0.5 wt. % of hydrogen peroxide based on the total weight of the composition. In some embodiments, the composition comprises from about 0.01 wt. % to about 5 wt. % of hydrogen peroxide. In certain embodiments, the composition comprises about 0.1 wt. % to about 2 wt. % of hydrogen peroxide.

The composition comprises a complexant. The complexant can be any suitable compound capable of coordinating with (e.g., chelating) one or more metals (e.g., ceria, iron, copper, etc.). For example, the complexant can be ethylenediamine tetraacetic acid (EDTA), hydroxyethylethylenediamine triacetic acid (HEDTA), cyclohexane diamine tetraacetic acid (CDTA), diethylenetriamine pentaacetic acid (DETPA), hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, citric acid, ascorbic acid, 4-(2-hydroxyethyl)-1-piperazineethane sulfonic acid (HEPES), [tris(hydroxymethyl)methylamino]propane sulfonic acid (TAPS), picolinic acid, dipicolinic acid, salts thereof, or combinations thereof. In some embodiments, the complexant is selected from ethylenediamine tetraacetic acid (EDTA), hydroxyethylethylenediamine triacetic acid (HEDTA), cyclohexane diamine tetraacetic acid (CDTA), diethylenetriamine pentaacetic acid (DETPA), hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, citric acid, ascorbic acid, picolinic acid, dipicolinic acid, salts thereof, and combinations thereof. In certain embodiments, the complexant is a phosphonate, i.e., a compound comprising a carbon-phosphorus bond. For example, the complexant can be hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, salts thereof, or combinations thereof. In preferred embodiments, the complexant is hydroxyethylidene diphosphonic acid (HEDP).

The composition can comprise any suitable amount of the complexant. The composition can comprise about 20 wt. % or less of the complexant based on the total weight of the composition, for example, about 10 wt. % or less, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the complexant based on the total weight of the composition. Alternatively, or in addition, the composition can comprise about 0.005 wt. % or more of the complexant based on the total weight of the composition, for example, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of the complexant based on the total weight of the composition. Thus, the composition can comprise the complexant in any amount bounded by any two of the aforementioned endpoints, as appropriate.

For example, in some embodiments, the complexant can be present in the composition in an amount of about 0.005 wt. % to about 20 wt. % based on the total weight of the composition, e.g., about 0.005 wt. % to about 10 wt. %, about 0.005 wt. % to about 8 wt. %, about 0.005 wt. % to about 6 wt. %, about 0.005 wt. % to about 5 wt. %, about 0.005 wt. % to about 4 wt. %, about 0.005 wt. % to about 2 wt. %, about 0.005 wt. % to about 1 wt. %, about 0.005 wt. % to about 0.05 wt. %, about 0.05 wt. % to about 20 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 20 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 20 wt. %, about 0.5 wt. % to about 10 wt. %, about 0.5 wt. % to about 8 wt. %, about 0.5 wt. % to about 6 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 20 wt. %, about 1 wt. % to about 10 wt. %, about 1 wt. % to about 8 wt. %, about 1 wt. % to about 6 wt. %, or about 1 wt. % to about 5 wt. % of the complexant based on the total weight of the composition. In some embodiments, the composition comprises about 0.1 wt. % to about 10 wt. % of the complexant. In certain embodiments, the composition comprises about 1 wt. % to about 5 wt. % of the complexant.

The composition comprises a fluoride salt. The fluoride salt can be any suitable fluoride salt such as, for example, an alkali metal salt, an alkaline earth metal salt, or a transition metal salt. In some embodiments, the fluoride salt is selected from ammonium fluoride, ammonium bifluoride, sodium fluoride, potassium fluoride, and combinations thereof. In certain embodiments, the fluoride salt is ammonium fluoride or ammonium bifluoride.

The composition can comprise any suitable amount of the fluoride salt. The composition can comprise about 20 wt. % or less of the fluoride salt based on the total weight of the composition, for example, about 10 wt. % or less, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the fluoride salt based on the total weight of the composition. Alternatively, or in addition, the composition can comprise about 0.005 wt. % or more of the fluoride salt based on the total weight of the composition, for example, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of the fluoride salt based on the total weight of the composition. Thus, the composition can comprise the fluoride salt in any amount bounded by any two of the aforementioned endpoints, as appropriate.

For example, in some embodiments, the fluoride salt can be present in the composition in an amount of about 0.005 wt. % to about 20 wt. % based on the total weight of the composition, e.g., about 0.005 wt. % to about 10 wt. %, about 0.005 wt. % to about 8 wt. %, about 0.005 wt. % to about 6 wt. %, about 0.005 wt. % to about 5 wt. %, about 0.005 wt. % to about 4 wt. %, about 0.005 wt. % to about 2 wt. %, about 0.005 wt. % to about 1 wt. %, about 0.005 wt. % to about 0.05 wt. %, about 0.05 wt. % to about 20 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 20 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 20 wt. %, about 0.5 wt. % to about 10 wt. %, about 0.5 wt. % to about 8 wt. %, about 0.5 wt. % to about 6 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 20 wt. %, about 1 wt. % to about 10 wt. %, about 1 wt. % to about 8 wt. %, about 1 wt. % to about 6 wt. %, or about 1 wt. % to about 5 wt. % of the fluoride salt based on the total weight of the composition. In some embodiments, the composition comprises about 0.1 wt. % to about 10 wt. % of the fluoride salt. In certain embodiments, the composition comprises about 1 wt. % to about 5 wt. % of the fluoride salt.

The composition comprises a sulfonated polymer (e.g., a homopolymer or a copolymer). The sulfonated polymer can be any suitable polymer comprising a sulfonic acid monomeric unit. The sulfonic acid monomer unit can be any suitable sulfonic acid monomer unit comprising one or more groups of the formula: —SO₃H. Exemplary sulfonic acid monomer units include, but are not limited to, vinyl sulfonic acid, styrene sulfonic acid (e.g., 4-styrene sulfonic acid), allylsulfonic acid, ethylacrylate sulfonic acid, butyl acrylate sulfonic acid, isoprene sulfonic acid, 2-acrylamido-2-methyl-1-propanesulfonic acid, 2-methylacrylamido-2-methylpropane sulfonic acid, 3-allyloxy-2-hydroxy-1-propanesulfonic acid, 2-sulfoethyl methacrylate, 2-sulfoethylacrylate, 3-sulfopropyl methacrylate, 3-sulfopropyl acrylate, and salts thereof. In some embodiments, the sulfonated polymer comprises a monomer unit derived from a monomer selected from 2-acrylamido-2-methylpropane sulfonic acid, 2-methylacrylamido-2-methylpropane sulfonic acid, styrene sulfonic acid, vinyl sulfonic acid, 3-allyloxy-2-hydroxy-1-propanesulfonic acid, 2-sulfoethyl methacrylate, 2-sulfoethylacrylate, 3-sulfopropyl methacrylate, 3-sulfopropyl acrylate, salts thereof, and combinations thereof. In certain embodiments, the sulfonated polymer (e.g., homopolymer or copolymer) comprises a monomer unit derived from a monomer selected from 2-acrylamido-2-methylpropane sulfonic acid, styrene sulfonic acid, salts thereof, and combinations thereof. The polymer comprising a sulfonic acid monomeric unit can be provided in its free acid form, as a salt thereof, or as a partial salt thereof.

In some embodiments, the sulfonated polymer is a homopolymer selected from poly-2-acrylamido-2-methylpropane sulfonic acid, poly-2-methylacrylamido-2-methylpropane sulfonic acid, polystyrene sulfonic acid (e.g., poly(4-styrenesulfonic acid)), polyvinyl sulfonic acid, poly-3-allyloxy-2-hydroxy-1-propanesulfonic acid, poly-2-sulfoethyl methacrylate, poly-2-sulfoethylacrylate, poly-3-sulfopropyl methacrylate, poly-3-sulfopropyl acrylate, and salts thereof. In other embodiments, the sulfonated polymer is a copolymer comprising a monomer unit derived from a monomer selected from 2-acrylamido-2-methylpropane sulfonic acid, 2-methylacrylamido-2-methylpropane sulfonic acid, styrene sulfonic acid, vinyl sulfonic acid, 3-allyloxy-2-hydroxy-1-propanesulfonic acid, 2-sulfoethyl methacrylate, 2-sulfoethylacrylate, 3-sulfopropyl methacrylate, 3-sulfopropyl acrylate, salts thereof and one or more additional monomer units. The one or more additional monomer units can be any suitable monomer unit capable of polymerization with the sulfonic acid monomeric unit. In some embodiments, the sulfonated polymer further comprises one or more additional monomer units derived from a (meth)acrylate monomer, a (meth)acrylamido monomer, a styrenic monomer, a vinylic monomer, or a combination thereof. Exemplary additional monomer units include, but are not limited to, (meth)acrylic acid (i.e., methacrylic acid or acryl acid), (meth)acrylamide (i.e., methacrylamide or acrylamide), hydroxypropylacrylate, tertiary butyl acrylamide, ethylene, propylene, isoprene, and styrene.

In embodiments where the sulfonated polymer is a copolymer, the copolymer can be any suitable copolymer. For example, the copolymer can be a random copolymer, a block copolymer, a graft copolymer, or an alternating copolymer.

In certain embodiments, the sulfonated polymer comprises a monomer unit derived from styrene sulfonic acid (e.g., 4-styrene sulfonic acid) or a salt thereof. In a preferred embodiment, the sulfonated polymer is polystyrene sulfonic acid or a salt thereof.

The sulfonated polymer can have any suitable weight average molecular weight. The sulfonated polymer can have a weight average molecular weight of about 50,000 g/mol or more, for example, about 55,000 g/mol or more, about 60,000 g/mol or more, about 65,000 g/mol or more, about 70,000 g/mol or more, about 75,0000 g/mol or more, about 80,000 g/mol or more, about 85,000 g/mol or more, about 90,000 g/mol or more, about 95,000 g/mol or more, about 100,000 g/mol or more, about 110,000 g/mol or more, about 120,000 g/mol or more, about 130,000 g/mol or more, about 140,000 g/mol or more, or about 150,000 g/mol or more. Alternatively, or in addition, the sulfonated polymer can have a weight average molecular weight of about 200,000 g/mol or less, for example, about 195,000 g/mol or less, about 190,000 g/mol or less, about 185,000 g/mol or less, about 180,000 g/mol or less, about 175,000 g/mol or less, about 170,000 g/mol or less, about 165,000 g/mol or less, about 160,000 g/mol or less, about 155,000 g/mol or less, or about 150,000 g/mol or less.

Thus, the sulfonated polymer can have a weight average molecular weight bounded by any two of the aforementioned endpoints. For example, the sulfonated polymer can have a weight average molecular weight of about 50,000 g/mol to about 200,000 g/mol, about 60,000 g/mol to about 200,000 g/mol, about 70,000 g/mol to about 200,000 g/mol, about 75,000 g/mol to about 200,000 g/mol, about 80,000 g/mol to about 200,000 g/mol, about 90,000 g/mol to about 200,000 g/mol, about 100,000 g/mol to about 200,000 g/mol, about 50,000 g/mol to about 190,000 g/mol, about 50,000 g/mol to about 180,000 g/mol, about 50,000 g/mol to about 170,000 g/mol, about 50,000 g/mol to about 160,000 g/mol, about 50,000 g/mol to about 150,000 g/mol, or about 75,000 g/mol to about 150,000 g/mol. In certain embodiments, the sulfonated polymer has a weight average molecular weight of about 200,000 g/mol or less (e.g., about 50,000 g/mol to about 200,000 g/mol).

The composition can comprise any suitable amount of the sulfonated polymer. The amount of the sulfonated polymer refers to the total amount of sulfonic acid polymer or copolymer present in the composition. The composition can comprise about 0.005 wt. % or more of the sulfonated polymer based on the total weight of the composition, for example, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of the sulfonated polymer based on the total weight of the composition. Alternatively, or in addition, the composition can comprise 20 wt. % or less of the sulfonated polymer based on the total weight of the composition, for example, about 10 wt. % or less, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the sulfonated polymer based on the total weight of the composition. Thus, the composition can comprise the sulfonated polymer in an amount bounded by any two of the aforementioned endpoints.

For example, the composition can comprise about 0.005 wt. % to about 20 wt. % of the sulfonated polymer based on the total weight of the composition, e.g., about 0.005 wt. % to about 10 wt. %, about 0.005 wt. % to about 8 wt. %, about 0.005 wt. % to about 6 wt. %, about 0.005 wt. % to about 5 wt. %, about 0.005 wt. % to about 4 wt. %, about 0.005 wt. % to about 2 wt. %, about 0.005 wt. % to about 1 wt. %, about 0.005 wt. % to about 0.05 wt. %, about 0.05 wt. % to about 20 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 20 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 20 wt. %, about 0.5 wt. % to about 10 wt. %, about 0.5 wt. % to about 8 wt. %, about 0.5 wt. % to about 6 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 20 wt. %, about 1 wt. % to about 10 wt. %, about 1 wt. % to about 8 wt. %, about 1 wt. % to about 6 wt. %, or about 1 wt. % to about 5 wt. % of the sulfonated polymer based on the total weight of the composition. In some embodiments, the composition comprises about 0.1 wt. % to about 10 wt. % of the sulfonated polymer based on the total weight of the composition. In certain embodiments, the composition comprises about 0.1 wt. % to about 1 wt. % of the sulfonated polymer based on the total weight of the composition.

In some embodiments, the composition further comprises sulfuric acid or a sulfate salt (i.e., a sulfate salt other than the sulfonated polymer). For example, the sulfuric acid and/or sulfate salt can be added to adjust the pH and/or buffer the composition. In other embodiments, the composition does not contain (i.e., do not include a detectable amount of) sulfuric acid and/or does not contain a sulfate salt (i.e., a sulfate salt other than the sulfonated polymer).

In some embodiments, the composition further comprises one or more water-miscible solvents. Exemplary water-miscible solvents include, but are not limited to, alcohols, glycols, and glycol ethers, including, but not limited to, methanol, ethanol, isopropanol, butanol, and higher alcohols (such as C₂-C₄ diols and C₂-C₄ triols), tetrahydrofurfuryl alcohol (THFA), halogenated alcohols (e.g., 3-chloro-1,2-propanediol, 3-chloro-1-propanethiol, 1-chloro-2-propanol, 2-chloro-1-propanol, 3-chloro-1-propanol, 3-bromo-1,2-propanediol, 1-bromo-2-propanol, 3-bromo-1-propanol, 3-iodo-1-propanol, 4-chloro-1-butanol, and 2-chloroethanol), dichloromethane, chloroform, acetic acid, propionic acid, trifluoroacetic acid, tetrahydrofuran N-methylpyrrolidinone (NMP), cyclohexylpyrrolidinone, N-octylpyrrolidinone, N-phenylpyrrolidinone, methyldiethanolamine, methyl formate, dimethyl formamide (DMF), dimethylsulfoxide (DMSO), tetramethylene sulfone (sulfolane), diethyl ether, phenoxy-2-propanol (PPh), propriophenone, ethyl lactate, ethyl acetate, ethyl benzoate, acetonitrile, acetone, ethylene glycol, propylene glycol (PG), 1,3-propanediol, dioxane, butyryl lactone, butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether (TEGMBE), ethylene glycol monohexyl ether, diethylene glycol monohexyl ether, ethylene glycol phenyl ether, propylene glycol methyl ether, propylene glycol monobutyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, ethylene glycol monophenyl ether, diethylene glycol monophenyl ether hexaethylene glycol monophenylether, dipropylene glycol methyl ether acetate, tetraethylene glycol dimethyl ether (TEGDE), dibasic ester, glycerine carbonate, N-formyl morpholine, triethyl phosphate, and combinations thereof.

The composition can comprise any suitable amount of the one or more water-miscible solvents, when present. The composition can comprise about 10 wt. % or less of the one or more water-miscible solvents, when present, based on the total weight of the composition, for example, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the one or more water-miscible solvents, when present, based on the total weight of the composition. Alternatively, or in addition, the composition can comprise about 0.005 wt. % or more of the one or more water-miscible solvents, when present, based on the total weight of the composition, for example, about 0.01 wt. % or more, 0.05 wt. % or more, about 0.1 wt. % or more, or about 0.5 wt. % or more of the one or more water-miscible solvents, when present, based on the total weight of the composition. Thus, the composition can comprise the one or more water-miscible solvents in any amount bounded by any two of the aforementioned endpoints, as appropriate.

For example, in some embodiments, the one or more water-miscible solvents can be present in the composition in an amount of about 0.005 wt. % to about 5 wt. % based on the total weight of the composition, e.g., about 0.005 wt. % to about 4 wt. %, about 0.005 wt. % to about 2 wt. %, about 0.005 wt. % to about 1 wt. %, about 0.005 wt. % to about 0.05 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 5 wt. %, about 0.1 wt. % to about 4 wt. %, about 0.1 wt. % to about 2 wt. %, or about 0.1 wt. % to about 1 wt. % of the water-miscible solvents based on the total weight of the composition. In some embodiments, the composition comprises about 0.1 wt. % to about 10 wt. % of the one or more water-miscible solvents, when present, based on the total weight of the composition. In certain embodiments, the composition comprises about 1 wt. % to about 5 wt. % of the one or more water-miscible solvents, when present, based on the total weight of the composition.

In some embodiments, the composition further comprises one or more water-dispersible or water-soluble polymers. Such polymers, when present, include but are not limited to methacrylic acid homopolymer, methacrylic acid copolymers with, for example, acrylamidomethylpropane sulfonic acid and maleic acid, maleic acid and vinyl ether copolymer; poly(vinylpyrrolidone) and vinyl acetate copolymer, phosphonated polyethyleneglycol oligomers, poly(acrylic acid) (PAA), poly(acrylamide), poly(vinyl acetate), poly(ethylene glycol) (PEG), polypropylene glycol (PPG), poly(styrene sulfonic acid), poly(vinyl sulfonic acid), poly(vinyl phosphonic acid), poly(vinyl phosphoric acid), poly(ethyleneimine), poly(propyleneimine), polyallylamine, polyethylene oxide (PEO), polyvinyl pyrrolidone (PVP), PPG-PEG-PPG block copolymers, PEG-PPG-PEG block copolymers, poly(vinyl alcohol), poly(hydroxyethyl)acrylate, poly(hydroxyethyl)methacrylate, hydroxyethyl cellulose, methylhydroxyethyl cellulose, hydroxypropyl cellulose, methylhydroxypropyl cellulose, xanthan gum, potassium alginate, pectin, carboxymethylcellulose, glucosamine, poly(diallyldimethylammonium) chloride, PEGylated (i.e., polyethyleneglycol-ated) methacrylate/acrylate copolymers, polyMADQuat (poly(2-methacryloxyethyltrimethylammonium chloride—CAS Number 26161-33-1) and copolymers thereof, dimethylaminomethacrylate polymers and copolymers thereof, trimethylammonium methylmethacrylate polymers and copolymers thereof, and combinations thereof. The copolymers above may be random or block copolymers. When present, the amount of the one or more water-dispersible or water-soluble polymers in the composition is in a range from about 0.0001 wt. % to about 5 wt. % based on the total weight of the composition. In some embodiments, the composition further comprises one or more water-dispersible or water-soluble polymers selected from poly(acrylic acid) (PAA), poly(ethylene glycol) (PEG), polyvinyl pyrrolidone (PVP), PPG-PEG-PPG block copolymers, PEG-PPG-PEG block copolymers, hydroxyethyl cellulose, methylhydroxyethyl cellulose, hydroxypropyl cellulose, methylhydroxypropyl cellulose, and combinations thereof. In certain embodiments, the composition further comprises one or more water-dispersible or water-soluble polymers selected from hydroxyethyl cellulose, poly(ethylene glycol) (PEG), polyvinyl pyrrolidone (PVP), and combinations thereof.

In some embodiments, the composition further comprises a biocide. The biocide can be any suitable biocide. For example, the biocide can be an isothiazolinone-based biocide such as Kordek MLX™ (DuPont, Wilmington, DE). In certain embodiments, the biocide is 5-chloro-2-methyl-4-isothiazolin-3-one, 2-methyl-4-isothiazolin-3-one, benzisothiazolone, 1,2-benzisothiazol-3[2H]-one, methylisothiazolinone, methylchloroisothiazolinone, or a combination thereof. The composition can comprise any suitable amount of the biocide. For example, the composition can comprise about 0.001 wt. % to about 0.2 wt. % of the biocide.

In some embodiments, the composition further comprises a pH adjustor. The pH adjustor can be any suitable compound capable of adjusting the pH of the composition to a pH of less than about 7. Exemplary pH adjustors include, but are not limited to bases such as, for example, potassium hydroxide, sodium hydroxide, ammonium hydroxide (i.e., aqueous ammonia), and quaternary bases having the formula (PR⁸R⁹R¹⁰R¹¹)OH, wherein R⁸, R⁹, R¹⁰, and R¹¹ are each independently chosen from hydrogen, straight-chain C₁-C₆ alkyl (e.g., methyl, ethyl, propyl, butyl, pentyl, and hexyl) groups, branched C₁-C₆ alkyl groups, C₁-C₆ hydroxyalkyl (e.g., hydroxymethyl, hydroxyethyl, hydroxypropyl, hydroxybutyl, hydroxypentyl, and hydroxyhexyl) groups, substituted C₆-C₁₀ aryl groups, and unsubstituted C₆-C₁₀ aryl groups (e.g., benzyl groups), such as tetrabutylphosphonium hydroxide (TBPH), tetramethylphosphonium hydroxide, tetraethylphosphonium hydroxide, tetrapropylphosphonium hydroxide, benzyltriphenylphosphonium hydroxide, methyl triphenylphosphonium hydroxide, ethyl triphenylphosphonium hydroxide, and N-propyl triphenylphosphonium hydroxide. Exemplary pH adjustors further include, but are not limited to acids such as, for example, nitric acid, sulfuric acid, phosphoric acid, methanesulfonic acid, and organic acids such as formic acid and acetic acid. In some embodiments, the pH adjustor is selected from potassium hydroxide, nitric acid, sulfuric acid, phosphoric acid, methanesulfonic acid, salts thereof, and combinations thereof.

The composition can comprise any suitable amount of the pH adjustor. Generally, the composition comprises the pH adjustor in an amount so as to maintain the pH of the composition in the range of less than about 7.

The composition can have any suitable pH. Typically, the composition has a pH of about 7 or less, e.g., about 6.5 or less, about 6 or less, about 5.5 or less, about 5 or less, about 4.5 or less, or about 4 or less. Alternatively, or in addition, the composition can have a pH of about 0 or more, e.g., about 0.5 or more, about 1 or more, about 1.5 or more, or about 2 or more. Thus, the composition can have a pH bounded by any two of the aforementioned endpoints. For example, the composition can have a pH of about 0 to about 7, e.g., about 0 to about 6, about 0 to about 5, about 0 to about 4, about 1 to about 7, about 1 to about 6, about 1 to about 5, about 1 to about 4, about 2 to about 7, about 2 to about 6, about 2 to about 5, or about 2 to 4. In some embodiments, the composition has a pH of about 2 to about 5. In certain embodiments, the composition has a pH of about 2 to about 4. The pH of the composition can be adjusted using any suitable pH adjustor described herein in sufficient quantities to achieve such pH ranges.

In some embodiments, the invention provides a composition comprising (a) water, (b) hydrogen peroxide, (c) a phosphonate complexant, (d) a fluoride salt, and (e) a sulfonated polymer.

In some embodiments, the invention provides a composition comprising (a) water, (b) hydrogen peroxide, (c) hydroxyethylidene diphosphonic acid (HEDP), (d) a fluoride salt, and (e) a sulfonated polymer.

In some embodiments, the invention provides a composition comprising (a) water, (b) hydrogen peroxide, (c) a complexant, (d) ammonium fluoride or ammonium bifluoride, and (e) a sulfonated polymer.

In some embodiments, the invention provides a composition comprising (a) water, (b) hydrogen peroxide, (c) a phosphonate complexant, (d) ammonium fluoride or ammonium bifluoride, and (e) a sulfonated polymer.

In some embodiments, the invention provides a composition comprising (a) water, (b) hydrogen peroxide, (c) hydroxyethylidene diphosphonic acid (HEDP), (d) ammonium fluoride or ammonium bifluoride, and (e) a sulfonated polymer.

In some embodiments, the invention provides a composition comprising (a) water, (b) hydrogen peroxide, (c) a complexant, (d) a fluoride salt, and (e) polystyrene sulfonic acid or a salt thereof.

In some embodiments, the invention provides a composition comprising (a) water, (b) hydrogen peroxide, (c) a phosphonate complexant, (d) a fluoride salt, and (e) polystyrene sulfonic acid or a salt thereof.

In some embodiments, the invention provides a composition comprising (a) water, (b) hydrogen peroxide, (c) hydroxyethylidene diphosphonic acid (HEDP), (d) a fluoride salt, and (e) polystyrene sulfonic acid or a salt thereof.

In some embodiments, the invention provides a composition comprising (a) water, (b) hydrogen peroxide, (c) a complexant, (d) ammonium fluoride or ammonium bifluoride, and (e) polystyrene sulfonic acid or a salt thereof.

In some embodiments, the invention provides a composition comprising (a) water, (b) hydrogen peroxide, (c) a phosphonate complexant, (d) ammonium fluoride or ammonium bifluoride, and (e) polystyrene sulfonic acid or a salt thereof.

In some embodiments, the invention provides a composition comprising (a) water, (b) hydrogen peroxide, (c) hydroxyethylidene diphosphonic acid (HEDP), (d) ammonium fluoride or ammonium bifluoride, and (e) polystyrene sulfonic acid or a salt thereof.

In some embodiments, the invention provides a composition comprising (a) water, (b) hydrogen peroxide, (c) a phosphonate complexant, (d) a fluoride salt, and (e) a sulfonated polymer, wherein the composition has a pH of about 2 to about 5 (e.g., about 2 to about 4).

In some embodiments, the invention provides a composition comprising (a) water, (b) hydrogen peroxide, (c) hydroxyethylidene diphosphonic acid (HEDP), (d) a fluoride salt, and (e) a sulfonated polymer, wherein the composition has a pH of about 2 to about 5 (e.g., about 2 to about 4).

In some embodiments, the invention provides a composition comprising (a) water, (b) hydrogen peroxide, (c) a complexant, (d) ammonium fluoride or ammonium bifluoride, and (e) a sulfonated polymer, wherein the composition has a pH of about 2 to about 5 (e.g., about 2 to about 4).

In some embodiments, the invention provides a composition comprising (a) water, (b) hydrogen peroxide, (c) a phosphonate complexant, (d) ammonium fluoride or ammonium bifluoride, and (e) a sulfonated polymer, wherein the composition has a pH of about 2 to about 5 (e.g., about 2 to about 4).

In some embodiments, the invention provides a composition comprising (a) water, (b) hydrogen peroxide, (c) hydroxyethylidene diphosphonic acid (HEDP), (d) ammonium fluoride or ammonium bifluoride, and (e) a sulfonated polymer, wherein the composition has a pH of about 2 to about 5 (e.g., about 2 to about 4).

In some embodiments, the invention provides a composition comprising (a) water, (b) hydrogen peroxide, (c) a complexant, (d) a fluoride salt, and (e) polystyrene sulfonic acid or a salt thereof, wherein the composition has a pH of about 2 to about 5 (e.g., about 2 to about 4).

In some embodiments, the invention provides a composition comprising (a) water, (b) hydrogen peroxide, (c) a phosphonate complexant, (d) a fluoride salt, and (e) polystyrene sulfonic acid or a salt thereof, wherein the composition has a pH of about 2 to about 5 (e.g., about 2 to about 4).

In some embodiments, the invention provides a composition comprising (a) water, (b) hydrogen peroxide, (c) hydroxyethylidene diphosphonic acid (HEDP), (d) a fluoride salt, and (e) polystyrene sulfonic acid or a salt thereof, wherein the composition has a pH of about 2 to about 5 (e.g., about 2 to about 4).

In some embodiments, the invention provides a composition comprising (a) water, (b) hydrogen peroxide, (c) a complexant, (d) ammonium fluoride or ammonium bifluoride, and (e) polystyrene sulfonic acid or a salt thereof, wherein the composition has a pH of about 2 to about 5 (e.g., about 2 to about 4).

In some embodiments, the invention provides a composition comprising (a) water, (b) hydrogen peroxide, (c) a phosphonate complexant, (d) ammonium fluoride or ammonium bifluoride, and (e) polystyrene sulfonic acid or a salt thereof, wherein the composition has a pH of about 2 to about 5 (e.g., about 2 to about 4).

In some embodiments, the invention provides a composition comprising (a) water, (b) hydrogen peroxide, (c) hydroxyethylidene diphosphonic acid (HEDP), (d) ammonium fluoride or ammonium bifluoride, and (e) polystyrene sulfonic acid or a salt thereof, wherein the composition has a pH of about 2 to about 5 (e.g., about 2 to about 4).

The compositions of the invention can be prepared and then sold in the form a concentrate, which contains water at a relatively low amount, and, consequently, a relatively concentrated amount of non-aqueous ingredients. The concentrate can be prepared commercially to be sold and transported while containing the concentrated amount of non-aqueous ingredients and relatively reduced amount of water, and to be eventually diluted by a purchaser of the concentrate at a point of use. The amounts of the different non-aqueous ingredients in the concentrate are amounts that, upon dilution of the concentrate, will result in desired amounts of those non-aqueous ingredients being present in the composition as ultimately utilized.

The composition of the invention can be easily prepared by simple addition of the respective ingredients and mixing to homogeneous condition, such as a solution. Furthermore, a composition may be readily formulated as single-package formulations or multi-part formulations that are mixed at or before the point of use, e.g., the individual parts of the multi-part formulation may be mixed by a user either at a processing tool (cleaning apparatus) or in a storage tank upstream of the processing tool.

Thus, the composition can be supplied as a one-package system comprising water, hydrogen peroxide, complexant, fluoride salt, sulfonated polymer, and/or any optional additive. Alternatively, the composition of the invention can be supplied as a two-package system. The two-package system allows for the adjustment of composition characteristics by changing the blending ratio of the two packages. Similarly, a three-, four-, or more package system can be utilized in connection with the invention, wherein each of multiple containers contains different components of the inventive composition, one or more optional additives, and/or one or more of the same components in different concentrations.

Accordingly, another aspect of the invention relates to a kit including, in two or more containers, various components of the composition described herein, suitable for storing and shipping the compositions and may include, for example, NOWPAK™ containers (Entegris, Inc., Billerica, MA, USA). Thus, the invention also provides a kit comprising, in two or more containers, two or more of:
(a) water,
(b) hydrogen peroxide,
(c) a complexant,
(d) a fluoride salt, and
(e) a sulfonated polymer.

The invention further provides a method for removing residue from a surface of a microelectronic device substrate, the method comprising (i) contacting the surface of the microelectronic device substrate with a composition comprising (a) water, (b) hydrogen peroxide, (c) a complexant, (d) a fluoride salt, and (e) a sulfonated polymer, and (ii) removing at least a portion of the residue from the surface of the microelectronic device substrate.

As used herein, the term “residue” (which is inclusive of a “contaminant”) refers to any material that is a chemical or particulate material that remains present at a surface of a microelectronic device substrate after a processing step used in the fabrication of a microelectronic device, for example, processing steps including plasma etching, plasma ashing (to remove photoresist from an etched wafer), chemical-mechanical processing (e.g., chemical-mechanical polishing), wet etching, etc. The residue may be any non-aqueous chemical material that is part of a processing composition used in the processing step, such as a chemical etchant, a photoresist, a CMP slurry, etc. The residue may alternately be a substance that is derived from a material of the processing composition during a processing step. Examples of these types of residues include non-aqueous, particulate or non-particulate, chemical or abrasive materials (e.g., abrasive particles, surfactant, oxidizer, corrosion inhibitor, catalyst) that remain at a surface of the substrate after processing. The residue may be originally present in a material such as a CMP slurry or an etching composition, such as a solid abrasive particle or chemical material present in a CMP abrasive slurry. Alternately, or additionally, a residue may be a by-product or a reaction product (in particulate (e.g., agglomerate or precipitate) or non-particulate form) that is generated during processing, e.g., a by-product or reaction product of a chemical present in a processing composition such as CMP slurry or wet etching composition, or a chemical that is present, used during, or produced during a plasma etching or a plasma ashing process.

The term “post-CMP residue” refers to residue that is present at an end of a CMP processing or polishing step, for example, a particle or chemical material that is present in or derived from a CMP slurry. Specific examples of post-CMP residues include, but are not limited to, abrasive particles (e.g., silica-containing or silica-based abrasive particles, metal oxide (e.g., alumina) particles, ceria or ceria-based particles, and the like), chemicals that are originally present in the slurry (e.g., an oxidizer, catalyst, surfactant, inhibitor, complexing agent, etc.), a metal, metal oxide, or metal complex that is derived from a metal material removed from the substrate surface being processed, or a reaction product or complex produced using a chemical of the slurry with another chemical of the slurry or with a chemical material derived from the substrate (e.g., a metal ion, pad particles, or any other material that is a product of the CMP process).

A “post-etch residue” refers to a material remaining following a gas-phase plasma etching process, e.g., back-end-of-line (“BEOL”) dual damascene processing, or wet etching processes. A post-etch residue may be organic, organometallic, organosilicic, or inorganic in nature, for example, silicon-containing material, carbon-based organic material, and etch gas residues such as oxygen residues and fluorine residues.

A “post-ash residue” refers to material remaining following oxidative or reductive plasma ashing to remove hardened photoresist and/or bottom anti-reflective coating (BARC) materials. The post-ash residue may be organic, organometallic, organosilicic, or inorganic in nature.

As noted above, the present invention relates to compositions which are useful in a cleaning method that removes residue from a surface of a microelectronic device substrate that has residue thereon. The compositions contain an aqueous carrier (i.e., water) along with a combination of other ingredients as set forth herein. In certain embodiments, the compositions, before being used in a cleaning process, are homogeneous solutions that comprise, consist of, or consist essentially of water and dissolved non-aqueous ingredients, in the absence of any solid or suspended materials such as solid abrasive particles, agglomerates, coagulates, etc.

The compositions as described herein are useful for cleaning microelectronic devices and precursors thereof, specifically including microelectronic device substrates, meaning semiconductor wafers that include on a surface one or more microelectronic devices or precursors thereof that are in the process of being fabricated into final, completed, and functional microelectronic devices.

The microelectronic device substrate can comprise any suitable material such as, for example, conductive materials or non-conductive materials (e.g., tantalum (Ta), tantalum nitride (TaNx), tungsten (W), titanium (Ti), titanium nitride (TiN), ruthenium (Ru), cobalt (Co), molybdenum (Mo), rhenium (Rh), and alloys thereof) and dielectric materials (e.g., PETEOS, SiO₂, thermal oxide, silicon nitride, silicon, etc.). In some embodiments, the microelectronic device substrate comprises a silicon oxide layer on a surface thereof.

As used herein, a microelectronic device is a device that includes electrical circuits and related structures of very small (e.g., micron-scale or smaller) dimensions formed thereon. Exemplary microelectronic devices include flat panel displays, integrated circuits, memory devices, solar panels, photovoltaics, and microelectromechanical systems (MEMS). A microelectronic device substrate is a structure such as a wafer (e.g., semiconductor wafer) that includes one or more microelectronic devices or precursors thereof, in a state of being prepared to form a final microelectronic device.

The compositions and methods described herein are useful to clean any of various forms of microelectronic devices, at any stage of processing. The compositions and method of the invention are effective to remove at least a portion of the residue from the surface of the microelectronic device substrate. In some embodiments, the compositions and methods described herein are effective to remove a substantial amount (e.g., at least 50% or more, at least 60% or more, or at least 70% or more) of residue from the surface, relative to an amount that is initially present at the surface before the cleaning step. In certain embodiments, a high percentage of residue that is present at a substrate surface can be successfully removed from the surface by use of compositions (i.e., cleaning compositions) and methods described herein. For example, the compositions (i.e., cleaning compositions) and methods described herein can be effective, in a cleaning step, to remove at least 80% of residue present on a surface of the substrate, e.g., at least 85% of residue, at least 90% of residue, at least 95% of residue, or at least 99% of residue from the surface, relative to an amount that is initially present at the surface before the cleaning step.

In some embodiments, the residue comprises ceria particles (i.e., ceria abrasive residue) the compositions and methods described herein are effective to remove a substantial amount (e.g., at least 50% or more, at least 60% or more, or at least 70% or more) of ceria abrasive residue from the surface, relative to an amount that is initially present at the surface before the cleaning step. In certain embodiments, a high percentage of ceria abrasive residue that is present at a substrate surface can be successfully removed from the surface by use of compositions (i.e., cleaning compositions) and methods described herein. For example, the compositions (i.e., cleaning compositions) and methods described herein can be effective, in a cleaning step, to remove at least 80% of ceria abrasive residue present on a surface of the substrate, e.g., at least 85% of ceria abrasive residue, at least 90% of ceria abrasive residue, at least 95% of ceria abrasive residue, or at least 99% of ceria abrasive residue from the surface, relative to an amount that is initially present at the surface before the cleaning step. Without wishing to be bound by any particular theory, it is believed that the compositions and methods described herein, comprising a fluoride salt, can etch cerium oxide and facilitate removal of ceria particles (i.e., ceria abrasive residue) from the surface of a microelectronic device without etching the dielectric surface. It is further believed that at low pH, e.g., at a pH of about 2 to about 5, H₂O₂ acts as a strong reducing agent which converts Ce(IV) to Ce(III), which, in the presence of a suitable chelating agent (e.g., HEDP), makes a soluble Ce(III)-complexant species. As a result, cerium can be readily solubilized in the cleaning composition and removed from a substrate.

Methods and equipment for measuring residue at a surface of a microelectronic device substrate are well-known. Cleaning efficiency may be rated based on a reduction of an amount (e.g., number) of residue particles present on a microelectronic device surface after cleaning, compared to the amount (e.g., number) of residue particles present before cleaning. For example, pre- and post-cleaning analysis may be carried out using an atomic force microscope. Residue particles on a surface may be registered as a range of pixels. A histogram (e.g., a Sigma Scan Pro) may be applied to filter the pixels in a certain intensity, e.g., 231-235, and the number of residue particles counted. The amount of residue particle removal, i.e., cleaning efficiency, may be calculated using the following ratio: (Number of PreClean Residue Particles on a Surface-Number of PostClean Residue Particles on the Surface)/(Number of PreClean Residue Particles on the Surface).

Alternately, cleaning efficiency may be considered as a percentage of a total amount of a substrate surface that is covered by residue particulate matter before as compared to after cleaning. For example, an atomic force microscope may be programmed to perform a z-plane scan to identify topographic areas of interest above a certain height threshold, and then calculate the area of the total surface covered by the areas of interest. A reduced amount of area determined to be areas of interest, after cleaning, indicates a more efficacious cleaning composition and cleaning process.

In a cleaning step, such as a post-CMP residue cleaning step, a cleaning composition may be used with any of a variety of known, conventional, commercially available cleaning tools such as megasonics and brush scrubbing, including, but not limited to, Verteq single wafer megasonic Goldfinger, OnTrak systems DDS (double-sided scrubbers), SEZ or other single wafer spray rinse, Applied Materials Mirra-MESA™/REFLEXION™/REFLEXION LK™, and Megasonic batch wet bench systems, and Ebara Technologies, Inc. products such as 300 mm models (FREX300S2 and FREX300X3SC) and the 200 mm CMP system (FREX200M).

Conditions and timing of a cleaning step can be as desired, and may vary depending on the type of substrate and residue. In use of a composition for cleaning post-CMP residue, post-etch residue, post-ash residue or contaminants from a microelectronic device substrate having the same thereon, the compositions (i.e., cleaning compositions) may be contacted with the substrate surface for a time of from about 1 second to about 20 minutes, e.g., from about 5 seconds to 10 minutes, or from about 15 seconds to about 5 minutes, at temperatures in a range of from about 20° C. to about 90° C., or about 20° C. to about 50° C. Such contacting times and temperatures are illustrative, and any other suitable time and temperature conditions may be useful if efficacious to at least partially clean an initial amount of residue from a surface.

Following the desired level of cleaning of a device substrate surface, the compositions (i.e., cleaning compositions) used in a cleaning step may be readily removed from the device surface, as may be desired and efficacious in a given end use application. For example, removal may be performed by use of a rinse solution that includes deionized water. Thereafter, the device may be processed as desired, such as by being dried (e.g., using nitrogen or a spin-dry cycle), followed by subsequent processing of the cleaned and dried device surface.

In other more general or specific methods, a microelectronic device substrate may first be subjected to a processing step that includes by any one or more of CMP processing, plasma etching, wet etching, plasma ashing, or the like, followed by a cleaning step that includes cleaning the substrate surface with the composition of the present invention. At the end of the first processing step, residue (e.g., post-etch residue, post-CMP residue, post ash residue, etc.) will be present at a surface of the substrate. The cleaning step, using a compositions (i.e., cleaning compositions) as described, will be effective to clean a substantial amount of the residue from the microelectronic device surface.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a phosphonate complexant, (d) a fluoride salt, and (e) a sulfonated polymer, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) hydroxyethylidene diphosphonic acid (HEDP), (d) a fluoride salt, and (e) a sulfonated polymer, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a complexant, (d) ammonium fluoride or ammonium bifluoride, and (e) a sulfonated polymer, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a phosphonate complexant, (d) ammonium fluoride or ammonium bifluoride, and (e) a sulfonated polymer, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) hydroxyethylidene diphosphonic acid (HEDP), (d) ammonium fluoride or ammonium bifluoride, and (e) a sulfonated polymer, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a complexant, (d) a fluoride salt, and (e) polystyrene sulfonic acid or a salt thereof, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a phosphonate complexant, (d) a fluoride salt, and (e) polystyrene sulfonic acid or a salt thereof, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) hydroxyethylidene diphosphonic acid (HEDP), (d) a fluoride salt, and (e) polystyrene sulfonic acid or a salt thereof, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a complexant, (d) ammonium fluoride or ammonium bifluoride, and (e) polystyrene sulfonic acid or a salt thereof, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a phosphonate complexant, (d) ammonium fluoride or ammonium bifluoride, and (e) polystyrene sulfonic acid or a salt thereof, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) hydroxyethylidene diphosphonic acid (HEDP), (d) ammonium fluoride or ammonium bifluoride, and (e) polystyrene sulfonic acid or a salt thereof, and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a phosphonate complexant, (d) a fluoride salt, and (e) a sulfonated polymer, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) hydroxyethylidene diphosphonic acid (HEDP), (d) a fluoride salt, and (e) a sulfonated polymer, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a complexant, (d) ammonium fluoride or ammonium bifluoride, and (e) a sulfonated polymer, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a phosphonate complexant, (d) ammonium fluoride or ammonium bifluoride, and (e) a sulfonated polymer, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) hydroxyethylidene diphosphonic acid (HEDP), (d) ammonium fluoride or ammonium bifluoride, and (e) a sulfonated polymer, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a complexant, (d) a fluoride salt, and (e) polystyrene sulfonic acid or a salt thereof, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a phosphonate complexant, (d) a fluoride salt, and (e) polystyrene sulfonic acid or a salt thereof, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) hydroxyethylidene diphosphonic acid (HEDP), (d) a fluoride salt, and (e) polystyrene sulfonic acid or a salt thereof, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a complexant, (d) ammonium fluoride or ammonium bifluoride, and (e) polystyrene sulfonic acid or a salt thereof, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) a phosphonate complexant, (d) ammonium fluoride or ammonium bifluoride, and (e) polystyrene sulfonic acid or a salt thereof, wherein the composition has a pH of about 2 to about 5 (e.g., about 2 to about 4), and (ii) removing at least a portion of the residue from the surface of the microelectronic device substrate.

In some embodiments, the invention further provides a method for removing residue from a surface of a microelectronic device substrate, the method comprising (i) contacting the surface of the microelectronic device substrate with a composition comprising (a) water, (b) hydrogen peroxide, (c) hydroxyethylidene diphosphonic acid (HEDP), (d) ammonium fluoride or ammonium bifluoride, and (e) polystyrene sulfonic acid or a salt thereof, wherein the composition has a pH of about 2 to about 5 (e.g., about 2 to about 4), and (ii) removing at least a portion of the residue from the surface of the microelectronic device substrate.

Aspects, including embodiments, of the invention described herein may be beneficial alone or in combination, with one or more other aspects or embodiments. Without limiting the foregoing description, certain non-limiting embodiments of the disclosure numbered 1-45 are provided below. As will be apparent to those of skill in the art upon reading this disclosure, each of the individually numbered embodiments may be used or combined with any of the preceding or following individually numbered embodiments. This is intended to provide support for all such combinations of embodiments and is not limited to combinations of embodiments explicitly provided below:

### EMBODIMENTS

(1) In embodiment (1) is presented a composition comprising:
(a) water,
(b) hydrogen peroxide,
(c) a complexant,
(d) a fluoride salt, and
(e) a sulfonated polymer.
(2) In embodiment (2) is presented the composition of embodiment (1), wherein the composition comprises from about 0.01 wt. % to about 5 wt. % of hydrogen peroxide.
(3) In embodiment (3) is presented the composition of embodiment (1) or embodiment (2), wherein the composition comprises from about 0.1 wt. % to about 2 wt. % of hydrogen peroxide.
(4) In embodiment (4) is presented the composition of any one of embodiments (1)-(3), wherein the complexant is selected from ethylenediamine tetraacetic acid (EDTA), hydroxyethylethylenediamine triacetic acid (HEDTA), cyclohexane diamine tetraacetic acid (CDTA), diethylenetriamine pentaacetic acid (DETPA), hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, citric acid, ascorbic acid, picolinic acid, dipicolinic acid, salts thereof, and combinations thereof.
(5) In embodiment (5) is presented the composition of any one of embodiments (1)-(4), wherein the complexant is a phosphonate.
(6) In embodiment (6) is presented the composition of any one of embodiments (1)-(5), wherein the complexant is selected from hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, salts thereof, and combinations thereof.
(7) In embodiment (7) is presented the composition of any one of embodiments (1)-(6), wherein the complexant is hydroxyethylidene diphosphonic acid (HEDP).
(8) In embodiment (8) is presented the composition of any one of embodiments (1)-(7), wherein the composition comprises about 0.1 wt. % to about 10 wt. % of the complexant.
(9) In embodiment (9) is presented the composition of any one of embodiments (1)-(8), wherein the composition comprises about 1 wt. % to about 5 wt. % of the complexant.
(10) In embodiment (10) is presented the composition of any one of embodiments (1)-(9), wherein the fluoride salt is selected from ammonium fluoride, ammonium bifluoride, sodium fluoride, potassium fluoride, and combinations thereof.
(11) In embodiment (11) is presented the composition of any one of embodiments (1)-(10), wherein the fluoride salt is ammonium fluoride or ammonium bifluoride.
(12) In embodiment (12) is presented the composition of any one of embodiments (1)-(11), wherein the composition comprises about 0.1 wt. % to about 10 wt. % of the fluoride salt.
(13) In embodiment (13) is presented the composition of any one of embodiments (1)-(12), wherein the composition comprises about 1 wt. % to about 5 wt. % of the fluoride salt.
(14) In embodiment (14) is presented the composition of any one of embodiments (1)-(13), wherein the sulfonated polymer comprises a monomer unit derived from a monomer selected from 2-acrylamido-2-methylpropane sulfonic acid, 2-methylacrylamido-2-methylpropane sulfonic acid, styrene sulfonic acid, vinyl sulfonic acid, 3-allyloxy-2-hydroxy-1-propanesulfonic acid, 2-sulfoethyl methacrylate, 2-sulfoethylacrylate, 3-sulfopropyl methacrylate, 3-sulfopropyl acrylate, salts thereof, and combinations thereof.
(15) In embodiment (15) is presented the composition of any one of embodiments (1)-(14), wherein the sulfonated polymer comprises a monomer unit derived from a monomer selected from 2-acrylamido-2-methylpropane sulfonic acid, styrene sulfonic acid, salts thereof, and combinations thereof.
(16) In embodiment (16) is presented the composition of embodiment (14) or embodiment (15), wherein the sulfonated polymer further comprises one or more additional monomer units derived from a monomer selected from a (meth)acrylate monomer, a (meth)acrylamido monomer, a styrenic monomer, a vinylic monomer, salts thereof, and combinations thereof.
(17) In embodiment (17) is presented the composition of any one of embodiments (1)-(15), wherein the sulfonated polymer is polystyrene sulfonic acid or a salt thereof.
(18) In embodiment (18) is presented the composition of any one of embodiments (1)-(17), wherein the composition comprises about 0.1 wt. % to about 10 wt. % of the sulfonated polymer.
(19) In embodiment (19) is presented the composition of any one of embodiments (1)-(18), wherein the composition comprises about 0.1 wt. % to about 1 wt. % of the sulfonated polymer.
(20) In embodiment (20) is presented the composition of any one of embodiments (1)-(19), wherein the composition further comprises sulfuric acid or a sulfate salt.
(21) In embodiment (21) is presented the composition of any one of embodiments (1)-(20), wherein the composition has a pH of about 2 to about 5.
(22) In embodiment (22) is presented the composition of any one of embodiments (1)-(21), wherein the composition has a pH of about 2 to about 4.
(23) In embodiment (23) is presented a method for removing residue from a surface of a microelectronic device substrate, the method comprising:
(i) contacting the surface of the microelectronic device substrate with a composition comprising:
   (a) water,
   (b) hydrogen peroxide,
   (c) a complexant,
   (d) a fluoride salt,
   (e) a sulfonated polymer, and
(ii) removing at least a portion of the residue from the surface of the microelectronic device substrate.
(24) In embodiment (24) is presented the method of embodiment (23), wherein the composition comprises from about 0.01 wt. % to about 5 wt. % of hydrogen peroxide.
(25) In embodiment (25) is presented the method of embodiment (23) or embodiment (24), wherein the composition comprises from about 0.1 wt. % to about 2 wt. % of hydrogen peroxide.
(26) In embodiment (26) is presented the method of any one of embodiments (23)-(25), wherein the complexant is selected from ethylenediamine tetraacetic acid (EDTA), hydroxyethylethylenediamine triacetic acid (HEDTA), cyclohexane diamine tetraacetic acid (CDTA), diethylenetriamine pentaacetic acid (DETPA), hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, citric acid, ascorbic acid, picolinic acid, dipicolinic acid, salts thereof, and combinations thereof.
(27) In embodiment (27) is presented the method of any one of embodiments (23)-(26), wherein the complexant is a phosphonate.
(28) In embodiment (28) is presented the method of any one of embodiments (23)-(27), wherein the complexant is selected from hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, salts thereof, and combinations thereof.
(29) In embodiment (29) is presented the method of any one of embodiments (23)-(28), wherein the complexant is hydroxyethylidene diphosphonic acid (HEDP).
(30) In embodiment (30) is presented the method of any one of embodiments (23)-(29), wherein the composition comprises about 0.1 wt. % to about 10 wt. % of the complexant.
(31) In embodiment (31) is presented the method of any one of embodiments (23)-(30), wherein the composition comprises about 1 wt. % to about 5 wt. % of the complexant.
(32) In embodiment (32) is presented the method of any one of embodiments (23)-(31), wherein the fluoride salt is selected from ammonium fluoride, ammonium bifluoride, sodium fluoride, potassium fluoride, and combinations thereof.
(33) In embodiment (33) is presented the method of any one of embodiments (23)-(32), wherein the fluoride salt is ammonium fluoride or ammonium bifluoride.
(34) In embodiment (34) is presented the method of any one of embodiments (23)-(33), wherein the composition comprises about 0.1 wt. % to about 10 wt. % of the fluoride salt.
(35) In embodiment (35) is presented the method of any one of embodiments (23)-(34), wherein the composition comprises about 1 wt. % to about 5 wt. % of the fluoride salt.
(36) In embodiment (36) is presented the method of any one of embodiments (23)-(35), wherein the sulfonated polymer comprises a monomer unit derived from a monomer selected from 2-acrylamido-2-methylpropane sulfonic acid, 2-methylacrylamido-2-methylpropane sulfonic acid, styrene sulfonic acid, vinyl sulfonic acid, 3-allyloxy-2-hydroxy-1-propanesulfonic acid, 2-sulfoethyl methacrylate, 2-sulfoethylacrylate, 3-sulfopropyl methacrylate, 3-sulfopropyl acrylate, salts thereof, and combinations thereof.
(37) In embodiment (37) is presented the method of any one of embodiments (23)-(36), wherein the sulfonated polymer comprises a monomer unit derived from a monomer selected from 2-acrylamido-2-methylpropane sulfonic acid, styrene sulfonic acid, salts thereof, and combinations thereof.
(38) In embodiment (38) is presented the method of embodiment (36) or embodiment (37), wherein the sulfonated polymer further comprises one or more additional monomer units derived from a monomer selected from a (meth)acrylate monomer, a (meth)acrylamido monomer, a styrenic monomer, a vinylic monomer, salts thereof, and combinations thereof.
(39) In embodiment (39) is presented the method of any one of embodiments (23)-(37), wherein the sulfonated polymer is polystyrene sulfonic acid or a salt thereof.
(40) In embodiment (40) is presented the method of any one of embodiments (23)-(39), wherein the composition comprises about 0.1 wt. % to about 10 wt. % of the sulfonated polymer.
(41) In embodiment (41) is presented the method of any one of embodiments (23)-(40), wherein the composition comprises about 0.1 wt. % to about 1 wt. % of the sulfonated polymer.
(42) In embodiment (42) is presented the method of any one of embodiments (23)-(41), wherein the composition further comprises sulfuric acid or a sulfate salt.
(43) In embodiment (43) is presented the method of any one of embodiments (23)-(42), wherein the composition has a pH of about 2 to about 5.
(44) In embodiment (44) is presented the method of any one of embodiments (23)-(43), wherein the composition has a pH of about 2 to about 4.
(45) In embodiment (45) is presented the method of any one of embodiments (23)-(44), wherein the residue comprises ceria particles.

### EXAMPLES

These following examples further illustrate the invention but, of course, should not be construed as in any way limiting its scope.

### Example 1

This example demonstrates the effect of hydrogen peroxide, a complexant (e.g., hydroxyethylidene diphosphonic acid (HEDP)), a fluoride salt (e.g., ammonium fluoride or ammonium bifluoride), and a sulfonated polymer (e.g., poly(4-styrenesulfonic acid) (PSSA)) on the cleaning performance of a composition prepared according to the invention.

Aqueous Cleaning Compositions 1A-1M were prepared using hydrogen peroxide (1 wt. % or 5 wt. %), poly(4-styrenesulfonic acid) (PSSA) (0.25 wt. %), hydroxyethylidene diphosphonic acid (HEDP) (0 wt. %, 3 wt. %, 6 wt. %, 9 wt. % or 15 wt. %), ammonium bifluoride or ammonium fluoride (1 wt. %, 2 wt. %, or 3 wt. %), acid (i.e., sulfuric acid, nitric acid, or phosphoric acid), and additive (i.e., dimethyl sulfoxide (DMSO) or hydroxyethyl cellulose (HEC)). The resulting solution was adjusted to a pH of 2.2 with the specific acid and diluted with water to a mass balance of 100 wt. %. The specific components and amounts thereof are set forth in Table 1.

TABLE 1
Cleaning Compositions 1A-1M

| Cleaning | H₂O₂ | HEDP | Fluoride salt | PSSA | Acid | Additive |
|---|---|---|---|---|---|---|
| Composition | (wt. %) | (wt. %) | (wt. %) | (wt. %) | (wt. %) | (wt. %) |
| 1A | 1 | 0 | NH₄HF₂ (1) | 0.25 | H₂SO₄ (6.01) | None |
| (Comparative) | | | | | | |
| 1B | 1 | 3 | NH₄HF₂ (1) | 0.25 | H₂SO₄ (6.01) | None |
| (Inventive) | | | | | | |
| 1C | 5 | 3 | NH₄HF₂ (1) | 0.25 | HNO₃ (6) | None |
| (Inventive) | | | | | | |
| 1D | 1 | 3 | NH₄HF₂ (1) | 0.25 | H₃PO₄ (6) | None |
| (Inventive) | | | | | | |
| 1E | 1 | 3 | NH₄HF₂ (1) | 0.25 | H₂SO₄ (6.09) | None |
| (Inventive) | | | | | | |
| 1F | 1 | 6 | NH₄HF₂ (1) | 0.25 | H₂SO₄ (4.56) | None |
| (Inventive) | | | | | | |
| 1G | 1 | 9 | NH₄HF₂ (1) | 0.25 | H₂SO₄ (2.95) | None |
| (Inventive) | | | | | | |
| 1H | 1 | 15 | NH₄HF₂ (1) | 0.25 | H₂SO₄ (1.75) | None |
| (Inventive) | | | | | | |
| 1I | 1 | 3 | NH₄HF₂ (2) | 0.25 | H₂SO₄ (6.91) | None |
| (Inventive) | | | | | | |
| 1J | 1 | 3 | NH₄HF₂ (3) | 0.25 | H₂SO₄ (7.2) | None |
| (Inventive) | | | | | | |
| 1K | 1 | 3 | NH₄F (1) | 0.25 | H₂SO₄ (6.04) | None |
| (Inventive) | | | | | | |
| 1L | 1 | 3 | NH₄HF₂ (1) | 0.25 | H₂SO₄ (6.01) | DMSO (3) |
| (Inventive) | | | | | | |
| 1M | 1 | 3 | NH₄HF₂ (1) | 0.25 | H₂SO₄ (6.01) | HEC (0.1) |
| (Inventive) | | | | | | |

Cleaning Compositions 1A-1M were subjected to the following cerium oxide (CeO₂) dissolution procedure, which included inductively coupled plasma (ICP) mass spectrometry for trace metal analysis.

CeO₂ (0.05 g) was added to a 50 mL metal-free centrifuge tube including a stir bar. To the metal-free centrifuge tube containing the CeO₂ (0.05 g) was added 30 grams of a 60-fold diluted (i.e., 1 gram of Cleaning Composition and 59 grams of deionized water) solution of Cleaning Compositions 1A-1M. Each of the resulting mixtures were placed on a stir plate for 5 minutes at 600 revolutions per minute. From each of the stirred mixtures was transferred 1.8 mL (×2) of the mixed solution into two separately labeled centrifuge tubes. The two centrifuge tubes were placed in an Eppendorf centrifuge opposite each other for counterbalance, and the tubes were centrifuged for 20 minutes at 15,000 revolutions per minute. The two centrifuge tubes were removed from the centrifuge and the resulting supernatant (from two centrifuge tubes per Cleaning Composition) were transferred to two separate pre-labeled metal-free 15 mL ICP tubes by pipetting 1 mL of the supernatant and adding 9 mL of a 2 wt. % nitric acid solution. The resulting samples were thoroughly mixed using a vortex and subjected to trace metal ICP-OES analysis. The average cerium concentrations for the two samples are set forth in Table 2.

TABLE 2
Cerium Concentration of Cleaning Compositions 1A-1M

Ce-ICP (ppm)

| Cleaning Composition | Average | Standard Deviation |
|---|---|---|
| 1A (Comparative) | 1 | 0.1 |
| 1B (Inventive) | 145 | 1.9 |
| 1C (Inventive) | 112 | 1.3 |
| 1D (Inventive) | 92 | 5.7 |
| 1E (Inventive) | 122 | 9.7 |
| 1F (Inventive) | 204 | 5.1 |
| 1G (Inventive) | 205 | 3.5 |
| 1H (Inventive) | 219 | 4.4 |
| 1I (Inventive) | 38 | 4.3 |
| 1J (Inventive) | 24 | 0.6 |
| 1K (Inventive) | 84 | 1.1 |
| 1L (Inventive) | 119 | 3.5 |
| 1M (Inventive) | 213 | 2.4 |

As is apparent from the results set forth in Table 2, Inventive Cleaning Compositions 1B-1M, containing a complexant (i.e., hydroxyethylidene diphosphonic acid (HEDP)), exhibited significantly higher cerium dissolution than Comparative Cleaning Composition, which did not contain a complexant. More particularly, Inventive Cleaning Compositions 1F-1H, containing 6 wt. % or more of HEDP, exhibited the highest cerium dissolution of all of the Cleaning Compositions tested. Without wishing to be bound by any particular theory, it is believed that at low pH, H₂O₂ acts as a strong reducing agent which converts Ce(IV) to Ce(III), which, in the presence of a suitable chelating agent (e.g., ITEDP), makes a soluble Ce(III)-complexant species. As a result, cerium can be readily solubilized in the cleaning composition and removed from a substrate.

The results in Table 2 also show that while H₂O₂ is necessary to convert Ce(IV) to Ce(III), increasing the concentration from 1 wt. % to 5 wt. % does not increase the dissolution of cerium in the cleaning composition. See, for example, Inventive Cleaning Compositions 1B and 1C. Similarly, while the fluoride salt is necessary to aid in etching the cerium oxide surface, increasing the concentration of fluoride salt in the cleaning composition does not significantly increase the dissolution of cerium in the cleaning performance. See, for example, Inventive Cleaning Compositions 1B, 1I, and 1J. In addition, Table 2 shows that a composition including ammonium bifluoride exhibits higher cerium dissolution than a composition including ammonium fluoride. See Inventive Cleaning Compositions 1B and 1K.

Table 2 further shows that adjusting the pH of the cleaning composition with different acids can also modify the cleaning performance. See, for example, Inventive Cleaning Compositions 1B, 1D, and 1E. In that respect, a composition including sulfuric acid exhibits higher cerium dissolution than a composition including phosphoric acid, which exhibits higher cerium dissolution than a composition including nitric acid.

The cleaning performance can be further adjusted by inclusion of a water-miscible solvent (e.g., DMSO or HEC) in the cleaning composition. See Inventive Cleaning Compositions 1B, 1L, and 1M. In that respect, Inventive Cleaning Composition 1L, containing DMSO, exhibits lower cerium dissolution than Inventive Cleaning Composition 1B, which does not contain DMSO. In contrast, Inventive Cleaning Composition 1M, containing HEC, exhibits higher cerium dissolution than Inventive Cleaning Composition 1, which does not contain HEC.

### Example 2

This example demonstrates the cleaning performance of inventive Cleaning Compositions 2A-2E. Aqueous Cleaning Compositions 2A-2E were prepared using hydrogen peroxide (1 wt. % or 5 wt. %), poly(4-styrenesulfonic acid) (PSSA) (0.25 wt. %, 0.75%), hydroxyethylidene diphosphonic acid (HEDP) (0 wt. %, 3 wt. %, 6 wt. %, 9 wt. % or 15 wt. %), ammonium bifluoride or ammonium fluoride (1 wt. %) acid (i.e., sulfuric acid, nitric acid, or phosphoric acid), and additive (i.e., dimethyl sulfoxide (DMSO) or hydroxyethyl cellulose (HEC)). The resulting solution was adjusted to a pH of 2.2 with the specific acid and diluted with water to a mass balance of 100 wt. %. The specific components and amounts thereof are set forth in Table 3.

TABLE 3
Cleaning Compositions 2A-2D

| | | Complexing | Fluoride | | | |
|---|---|---|---|---|---|---|
| Cleaning | H₂O₂ | agent | salt | PSSA | Acid | Additive |
| Composition | (wt. %) | (wt. %) | (wt. %) | (wt. %) | (wt. %) | (wt. %) |
| 2A | 1 | HEDP (3) | NH₄HF₂ (1) | 0.25 | H₂SO₄ (6.0) | None |
| (Inventive) | | | | | | |
| 2B | 1 | HEDP (6) | NH₄HF₂ (1) | 0.25 | H₂SO₄ (4.8) | HEC |
| (Inventive) | | | | | | |
| 2C | 1 | HEDP (6) | NH₄HF₂ (1) | 0.75 | None | HEC |
| (Inventive) | | | | | | |
| 2D | 1 | Dequest | NH₄HF₂ (1) | 0.75 | None | HEC |
| (Inventive) | | 7000 (6) | | | | |

In order to measure the cleaning performance of inventive formulations, 300 mm TEOS silicon oxide (prepared from tetraethoxysilane) coated on silicon wafers are polished using a ceria slurry (Entegris iDIEL® D7400C) on AMAT Reflexion® CMP tool with integrated brush cleaner. Polished wafers are cleaned by buffing (Down force 1 psi) on a second platen using Cleaning Compositions 2A-2D on Fujibo pad. After buffing wafers are transferred in to brush cleaner. Defect data was collected with KLATencor's Surfscan® SP7 and HITACHI SEM. Defect review was conducted to quantify the number of surface defects and are set forth in Table 4. Further these metal contamination on the wafer surface is measured by Vapor Phase Decomposition method with using Perkin-Elmer NexION 350S and the cleaning composition 2A-2D shows cerium level below their detection limit (<Detection limit 5E+09 atom/cm2)

TABLE 4
Cleaning Performance of 2A-2D

| Cleaning | Ceria particle Defects |
|---|---|
| Composition | Threshold @50 nm |
| 2A | 8 |
| (Inventive) | |
| 2B | 4 |
| Inventive | |
| 2C | 3 |
| Inventive | |
| 2D | 9 |
| Inventive | |

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A composition comprising:
(a) water,
(b) about 0.01 wt. % to about 5 wt. % of hydrogen peroxide,
(c) about 0.1 wt. % to about 10 wt. % of a complexant,
(d) about 0.1 wt. % to about 10 wt. % of a fluoride salt, and
(e) about 0.1 wt. % to about 10 wt. % of a sulfonated polymer.

2. The composition of claim 1, wherein the composition comprises from about 0.1 wt. % to about 2 wt. % of hydrogen peroxide.

3. The composition of claim 1, wherein the complexant is selected from ethylenediamine tetraacetic acid (EDTA), hydroxyethylethylenediamine triacetic acid (HEDTA), cyclohexane diamine tetraacetic acid (CDTA), diethylenetriamine pentaacetic acid (DETPA), hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, citric acid, ascorbic acid, picolinic acid, dipicolinic acid, salts thereof, and combinations thereof.

4. The composition of claim 1, wherein the complexant is a phosphonate.

5. The composition of claim 1, wherein the complexant is selected from hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, salts thereof, and combinations thereof.

6. The composition of claim 1, wherein the composition comprises about 1 wt. % to about 5 wt. % of the complexant.

7. The composition of claim 1, wherein the fluoride salt is selected from ammonium fluoride, ammonium bifluoride, sodium fluoride, potassium fluoride, and combinations thereof.

8. The composition of claim 1, wherein the fluoride salt is ammonium fluoride or ammonium bifluoride.

9. The composition of claim 1, wherein the composition comprises about 1 wt. % to about 5 wt. % of the fluoride salt.

10. The composition of claim 1, wherein the sulfonated polymer comprises a monomer unit derived from a monomer selected from 2-acrylamido-2-methylpropane sulfonic acid, 2-methylacrylamido-2-methylpropane sulfonic acid, styrene sulfonic acid, vinyl sulfonic acid, 3-allyloxy-2-hydroxy-1-propanesulfonic acid, 2-sulfoethyl methacrylate, 2-sulfoethylacrylate, 3-sulfopropyl methacrylate, 3-sulfopropyl acrylate, salts thereof, and combinations thereof.

11. The composition of claim 10, wherein the sulfonated polymer further comprises one or more additional monomer units derived from a monomer selected from a (meth)acrylate monomer, a (meth)acrylamido monomer, a styrenic monomer, a vinylic monomer, salts thereof, and combinations thereof.

12. The composition of claim 1, wherein the sulfonated polymer is polystyrene sulfonic acid or a salt thereof.

13. The composition of claim 1, wherein the composition comprises about 0.1 wt. % to about 1 wt. % of the sulfonated polymer.

14. The composition of claim 1, wherein the composition further comprises sulfuric acid or a sulfate salt.

15. The composition of claim 1, wherein the composition has a pH of about 2 to about 4.

16. A method for removing residue from a surface of a microelectronic device substrate, the method comprising:
(i) contacting the surface of the microelectronic device substrate with a composition comprising:
(a) water,
(b) about 0.01 wt. % to about 5 wt. % of hydrogen peroxide hydrogen peroxide,
(c) about 0.1 wt. % to about 10 wt. % of a complexant,
(d) about 0.1 wt. % to about 10 wt. % of a fluoride salt, and
(e) about 0.1 wt. % to about 10 wt. % of a sulfonated polymer,
wherein the composition has a pH of about 2 to about 5, and
(ii) removing at least a portion of the residue from the surface of the microelectronic device substrate.

17. The method of claim 16, wherein the complexant is selected from ethylenediamine tetraacetic acid (EDTA), hydroxyethylethylenediamine triacetic acid (HEDTA), cyclohexane diamine tetraacetic acid (CDTA), diethylenetriamine pentaacetic acid (DETPA), hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, citric acid, ascorbic acid, picolinic acid, dipicolinic acid, salts thereof, and combinations thereof.

18. The method of claim 16, wherein the complexant is selected from hydroxyethylidene diphosphonic acid (HEDP), diethylenetriamine pentamethylene phosphonic acid, bis(hexamethylene)triaminepenta(methylenephosphonic) acid, nitrilotri(methylphosphonic acid), hexamethylenediamine-N,N,N′,N′-tetrakis(methylphosphonic acid), 2-phosphono-1,2,4-butane carboxylic acid, salts thereof, and combinations thereof.

19. The method of claim 16, wherein the fluoride salt is selected from ammonium fluoride, ammonium bifluoride, sodium fluoride, potassium fluoride, and combinations thereof.

20. The method of claim 16, wherein the residue comprises ceria particles.
